(19) United States
(12) Patent Application Publication
(10) Pub. No.: US 2026/0322371 A1
(43) Pub. Date: Oct. 15, 2026

(54) SWITCHING CONTROL CIRCUIT AND SEMICONDUCTOR DEVICE

(71) Applicant: FUJI ELECTRIC CO., LTD., Kawasaki-shi (JP)

(72) Inventor: Shinichiro ADACHI, Matsumoto-city (JP)

(73) Assignee: FUJI ELECTRIC CO., LTD., Kawasaki-shi (JP)

(21) Appl. No.: 19/691,276

(22) Filed: May 28, 2026

Related U.S. Application Data
(63) Continuation of application No. PCT/JP2025/016843, filed on May 8, 2025.

(30) Foreign Application Priority Data
Jun. 14, 2024 (JP) 2024-096758

(51) Int. Cl. H03K 17/0812; H02J 7/68; H03F 3/213

(52) U.S. Cl. CPC H03K 17/08128; H02J 7/68; H03F 3/213; H02J 2207/50; H03F 2200/393

(57) ABSTRACT

A switching control circuit for a load drive circuit that includes first and second switching devices connected in series, and a free-wheeling diode connected in parallel to the first switching device. The load drive circuit drives a load. The switching control circuit includes: a charging circuit that, responding to a drive signal reaching a first level, charges the control electrode of the second switching device, for a first time period with a first current that increases with an increase in a load current, and subsequently charges the control electrode, for a second time period, with a second current; and an off circuit that, responding to the drive signal reaching a second level, turns off the second switching device. The second time period includes a time period during which a reverse recovery current flows through the free-wheeling diode when the load current reaches a maximum.

### CROSS-REFERENCE TO RELATED APPLICATIONS

This is a continuation application of International Patent Application No. PCT/JP2025/016843, filed May 8, 2025, which claims the benefit of priority to Japanese Patent Application No. 2024-096758, filed Jun. 14, 2024, the entire contents of each of which are hereby incorporated herein by reference.

### BACKGROUND

### Technical Field

The present disclosure relates to a switching control circuit and a semiconductor device.

### Description of the Related Art

In typical voltage-driven switching control circuits, the gate resistance of a switching device is adjusted, to thereby adjust power loss and surge voltage.

Further, as switching control circuits that improve the trade-off relationship between power loss and surge voltage, current-driven switching control circuits are known (for example, Japanese Patent Application Publication No. 2016-073052).

However, the disclosure described in Japanese Patent Application Publication No. 2016-073052 has such an issue as increased complexity and higher costs, due to the needs for a converter circuit such as an A/D converter or the like.

### SUMMARY

A first aspect of the present disclosure is a switching control circuit for a load drive circuit that includes a first switching device on a power supply side of the switching control circuit, a second switching device on a ground side of the switching control circuit, and connected to the first switching device in series, the second switching device having a control electrode that has a capacitance, and a free-wheeling diode connected in parallel to the first switching device, the load drive circuit being configured to drive a load to have a load current flow therethrough, the switching control circuit being configured to switch the second switching device, the switching control circuit comprising: a charging circuit configured to, in response to a drive signal reaching a first level, charge the capacitance of the control electrode of the second switching device, for a first time period with a first current, the first current increasing with an increase in the load current, and subsequently charge the capacitance, for a second time period, with a second current that is smaller than the first current; and an off circuit configured to, in response to the drive signal reaching a second level, turn off the second switching device, the second time period including a time period during which a reverse recovery current flows through the free-wheeling diode when the load current reaches a maximum thereof.

A second aspect of the present disclosure is a semiconductor device, comprising: a load drive circuit, including: a first switching device on a power supply side of the semiconductor device, a second switching device on a ground side of the semiconductor device, the second switching device having a control electrode that has a capacitance, and a free-wheeling diode that is connected in parallel to the first switching device, the load drive circuit being configured to drive a load to have a load current flow therethrough; a resistor configured to generate a voltage corresponding to a current of the second switching device; and a switching control circuit configured to switch the second switching device, the switching control circuit including a charging circuit configured to, in response to a drive signal reaching a first level, charge the capacitance of the control electrode of the second switching device, for a first time period, with a first current that increases with a rise in a voltage across the resistor, and subsequently charge the capacitance, for a second time period, with a second current that is smaller than the first current, and an off circuit configured to, in response to the drive signal reaching a second level, turn off the second switching device, the second time period including a time period during which a reverse recovery current flows through the free-wheeling diode when the load current reaches a maximum thereof.

### BRIEF DESCRIPTION OF THE DRAWINGS

FIG. 1 is a diagram illustrating a configuration of a power module 10 of an embodiment and a typical power module 50.

FIG. 2 is a diagram explaining a configuration of a typical voltage-driven Low Voltage Integrated Circuit (LVIC) 60.

FIGS. 3A and 3B are diagrams illustrating numerical simulation results for a voltage-driven LVIC 60.

FIG. 4 is a diagram illustrating an example of a configuration of an LVIC 22 in an embodiment.

FIG. 5 is a diagram for explaining a low current output circuit 25 of an embodiment.

FIG. 6 is a diagram for explaining a high current output circuit 27 of an embodiment.

FIG. 7 is a diagram illustrating an example of a configuration of a sample-and-hold circuit 44.

FIG. 8 is a diagram for explaining an operation of a charging circuit 23 of an embodiment.

FIGS. 9A and 9B are diagrams explaining current I_{c} dependence and temperature dependence of a voltage V_{SE} and current I_{C} dependence and temperature dependence of a current I_{G}.

FIG. 10 is a diagram explaining switching performed by an LVIC 22 of an embodiment.

FIG. 11 is a diagram explaining switching performed by an LVIC 22 of an embodiment.

FIG. 12 is a diagram explaining switching performed by an LVIIC 22 of an embodiment.

FIG. 13 is a diagram explaining switching performed by an LVIC 22 of an embodiment.

FIG. 14 is a diagram explaining switching performed by an LVIC 22 of an embodiment.

FIGS. 15A and 15B are diagrams explaining time periods T1 and T2.

FIGS. 16A and 16B are diagrams explaining time periods T1 and T2.

FIGS. 17A and 17B illustrate numerical simulation results of an LVIC 22 of an embodiment and an LVIC 60 of a comparative example.

FIG. 18 illustrates numerical simulation results of an LVIC 22 of an embodiment and an LVIC 60 of a comparative example.

FIG. 19 illustrates numerical simulation results of an LVIC 22 of an embodiment and an LVIC 60 of a comparative example.

FIG. 20 illustrates numerical simulation results of an LVIC 22 of an embodiment and an LVIC 60 of a comparative example.

### DETAILED DESCRIPTION

At least following matters will become apparent from the descriptions of the present specification and the accompanying drawings.

Embodiments of the present disclosure will be described below with reference to the drawings. The same or equivalent constituent elements, members, and the like illustrated in the drawings are given the same reference numerals, and repetitive description is omitted as appropriate.

### EMBODIMENT(S)

### <<Overview of Power Module 10>>

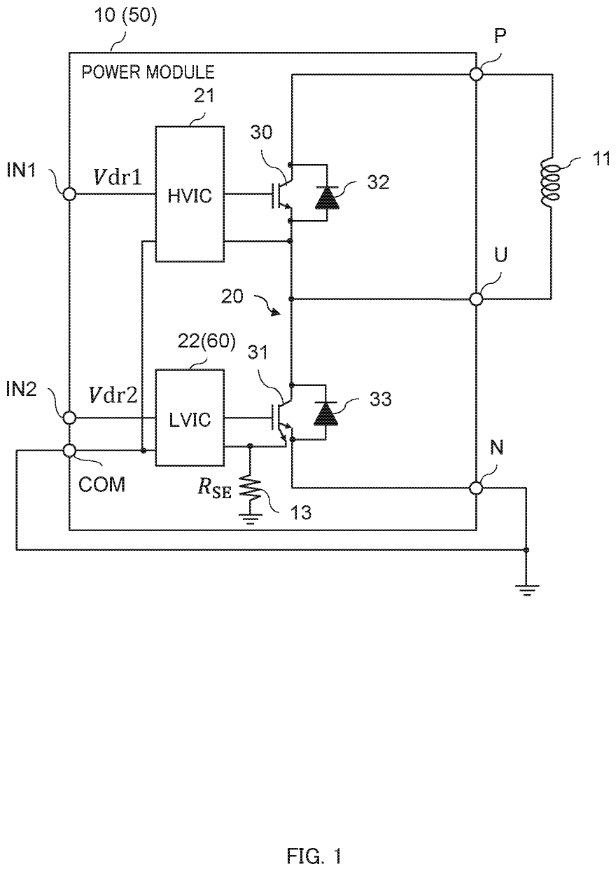

FIG. 1 is a diagram illustrating a configuration of a power module 10 (corresponding to a “semiconductor device”) according to an embodiment of the present disclosure. The power module 10 is a semiconductor device that drives an inductor 11, which is a load, for example, and includes a half-bridge circuit 20, a High Voltage Integrated Circuit (HVIC) 21, a Low Voltage Integrated Circuit (LVIC) 22, and terminals IN1, IN2, COM, P, U, N, and S.

The half-bridge circuit 20 drives the inductor 11, which is a load (described later). The half-bridge circuit 20 includes Insulated Gate Bipolar Transistors (IGBTs) 30, 31, and Free Wheeling Diodes (FWDs) 32, 33. Note that the half-bridge circuit 20 corresponds to a “load drive circuit”.

The IGBT 30 is a switching device of an upper arm that is provided on the power supply side, and the IGBT 31 is a switching device of a lower arm that is provided on the ground side and connected in series with the IGBT 30. Note that the IGBT 30 corresponds to a “first switching device”, and the IGBT 31 corresponds to a “second switching device”.

The FWD 32 is a free-wheeling diode that is connected in parallel to the IGBT 30 and recirculates the energy of the inductor 11. The FWD 32 has a cathode connected to the collector electrode of the IGBT 30, and an anode connected to the emitter electrode of the IGBT 30.

The FWD 33 is a free-wheeling diode that is connected in parallel to the IGBT 31. The FWD 33 has a cathode connected to the collector electrode of the IGBT 31, and an anode connected to the emitter electrode of the IGBT 31.

Note that the FWD 32 and the FWD 33 may be formed as part of the IGBT 30 and the IGBT 31, respectively. In this case, the IGBT 30 and the IGBT 31 may be a Reverse Conducting IGBT (RC-IGBT), for example.

A predetermined power supply voltage is applied to the terminal P, and the inductor 11, which is a load, is provided between the terminal P and the terminal U. Thus, the inductor 11 and the half-bridge circuit 20 constitute a chopper circuit. Note that the inductor 11 corresponds to a “load”.

A resistor 13 to detect the collector current I_{C} flowing through the IGBT 31 is connected between the IGBT 31 and the ground.

The aforementioned IGBT 31 is a device including a large-sized IGBT that controls an inductor current IL and a small-sized IGBT for current detection, and the current from the IGBT for current detection is supplied to the resistor 13. Accordingly, a voltage V_{SE} according to the current flowing through the IGBT 31 and the inductor current IL, which is a load, is generated across the resistor 13. In an embodiment of the present disclosure, the voltage generated across the resistor 13 is referred to as “voltage V_{SE}”.

In this case, there is no load connected between the terminal U and the terminal N, however, if an inductor is connected between the terminal U and the terminal N, the FWD 33 will operate as a free-wheeling diode.

The High Voltage Integrated Circuit (HVIC) 21 is an integrated circuit to switch the IGBT 30 of the upper arm. The HVIC 21 switches the IGBT 30 in response to a drive signal Vdr1 inputted through the terminal IN1 from a microcontroller (not illustrated).

The Low Voltage Integrated Circuit (LVIC) 22 is an integrated circuit to switch the IGBT 31 of the lower arm. The LVIC 22 switches the IGBT 31 in response to a drive signal Vdr2 inputted through the terminal IN2 from the microcontroller (not illustrated).

The terminal COM is a terminal to receive a grounding voltage, and is connected to the housing of the power module 10 (not illustrated), or the like, for example.

### <<Switching of IGBT 31 by Typical Voltage-Driven LVIC>>

Here, with reference to FIGS. 1 to 3, the switching of the IGBT 31 by a typical voltage-driven LVIC 60 will be explained.

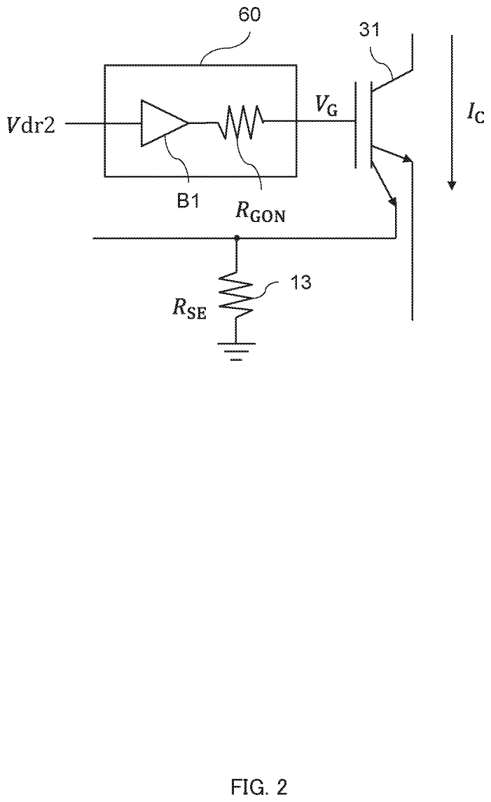

FIG. 2 is a diagram explaining a configuration of the LVIC 60 in a typical power module 50 illustrated in FIG. 1. The LVIC 60 includes a buffer circuit B1 and a resistor R_{GON}. The following describes the switching of the IGBT 31 of the lower arm in particular.

For example, in response to the drive signal Vdr2 reaching a high level (hereinafter referred to as high or high level), a predetermined voltage Vcc (for example, “15V”) is applied to the gate electrode of the IGBT 31 through the resistor R_{GON}.

On the other hand, in response to the drive signal Vdr2 reaching a low level (hereinafter referred to as low or low level), a ground voltage (here, “0 V”) is applied to the gate electrode of the IGBT 31 through the resistor R_{GON}.

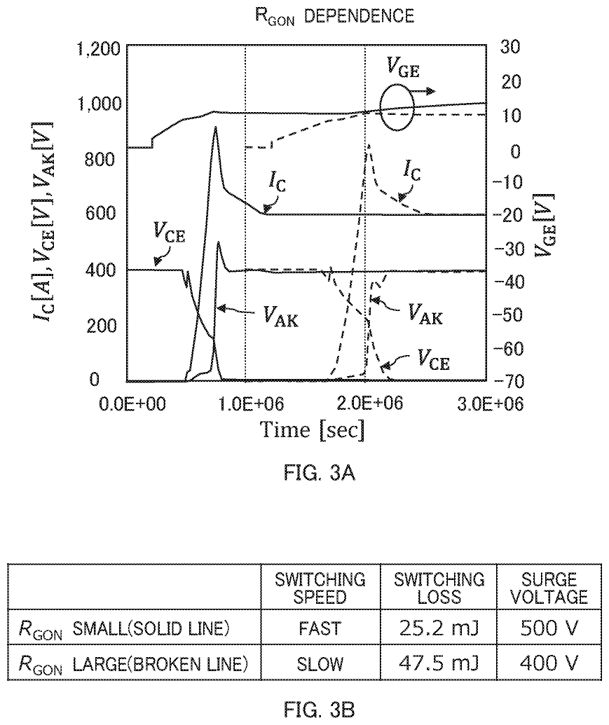

FIGS. 3A and 3B are diagrams illustrating numerical simulation results with respect to the LVIC 60. The horizontal axis of FIG. 3A represents time, while the vertical axis thereof represents the collector-emitter voltage V_{CE} of the IGBT 31, the gate-emitter voltage V_{GE} of the IGBT 31, the collector current I_{C} flowing through the IGBT 31, and the voltage VAK across the FWD 32.

Further, FIGS. 3A and 3B give the results with respect to the resistor R_{GON} under two conditions (large and small), where FIG. 3A gives the results with respect to the resistor R_{GON} being small by a solid line and the results with respect to the resistor R_{GON} being large by a broken line.

It is assumed that when the resistor R_{GON} is small, the drive signal Vdr2 goes high at time 0.0E+00 [sec], and when the resistor R_{GON} is large, the drive signal Vdr2 goes high at time 1.0E+00 [sec].

As can be seen from the current I_{C} in FIG. 3A, the smaller the resistor R_{GON}, the shorter the time taken to reach the current flowing through the load (which refers to the current I_{C} after a sufficient time has elapsed since the beginning of the time period during which the IGBT 31 is on; 600 A in this example) after the drive signal Vdr2 goes high. In other words, the smaller the resistor R_{GON}, the faster a switching speed.

Further, the switching loss derived from the results in FIG. 3A is 25.2 mJ when the resistor R_{GON} is small, and 47.5 mJ when the resistor R_{GON} is large (FIG. 3B). In other words, the larger the resistor R_{GON}, the greater a switching loss.

Further, as can be seen from the voltage VAK in FIG. 3A, the surge voltage (referring to the peak value of the voltage VAK) is 500 V when the resistor R_{GON} is small, while the surge voltage is 400 V when the resistor R_{GON} is large (FIG. 3B). In other words, the smaller the resistor R_{GON}, the larger the surge voltage.

As indicated by the above results, in the switching performed by the LVIC 60, when the resistor R_{GON} is made small, the switching loss decreases, but the surge voltage increases. Further, when the resistor R_{GON} is made large, the surge voltage decreases, but the switching loss increases. In other words, in the typical voltage-driven LVIC 60, there exists a trade-off relationship between the switching loss and the surge voltage.

### <<<Configuration of LVIC 22>>>

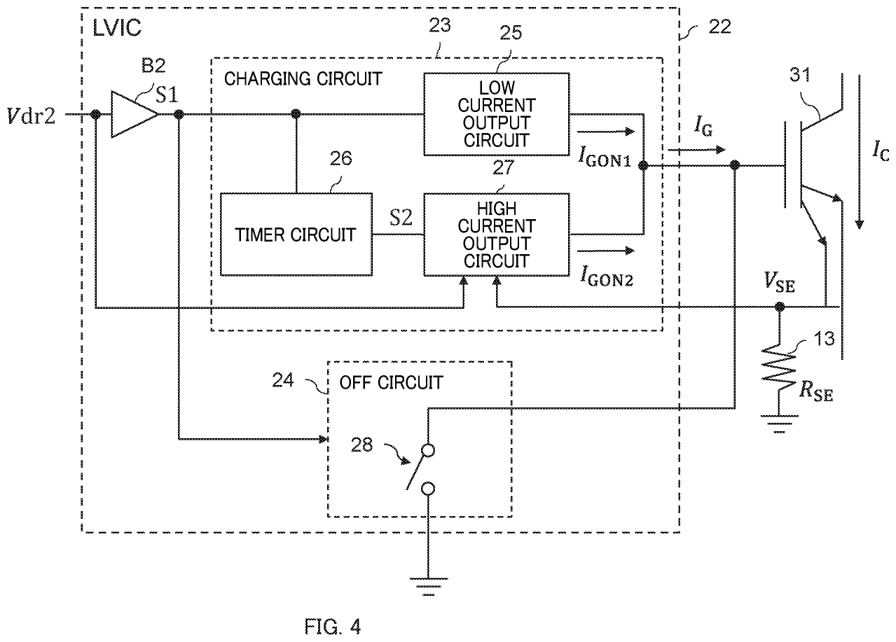

FIG. 4 is a diagram illustrating an example of a configuration of the LVIC 22 (corresponding to a “switching control circuit”) in an embodiment of the present disclosure. The LVIC 22 is an integrated circuit that turns on and off the IGBT 31 in response to the drive signal Vdr2, while improving the trade-off relationship between the switching loss and the surge voltage.

Further, the LVIC 22 is a current-driven LVIC, which is different from the LVIC 60 of FIG. 2 (which will be described in detail later). The LVIC 22 includes a buffer circuit B2, a charging circuit 23, and an off circuit 24.

The buffer circuit B2 receives the drive signal Vdr2 and outputs a signal S1 having a logic level equal to that of the drive signal Vdr2, to the charging circuit 23 and the off circuit 24. The charging circuit 23 is a circuit to charge the capacitance of the gate electrode of the IGBT 31 in order to turn on the IGBT 31, in response to the drive signal Vdr2. In this event, the charging circuit 23 supplies a gate current I_{G} to the gate electrode of the IGBT 31.

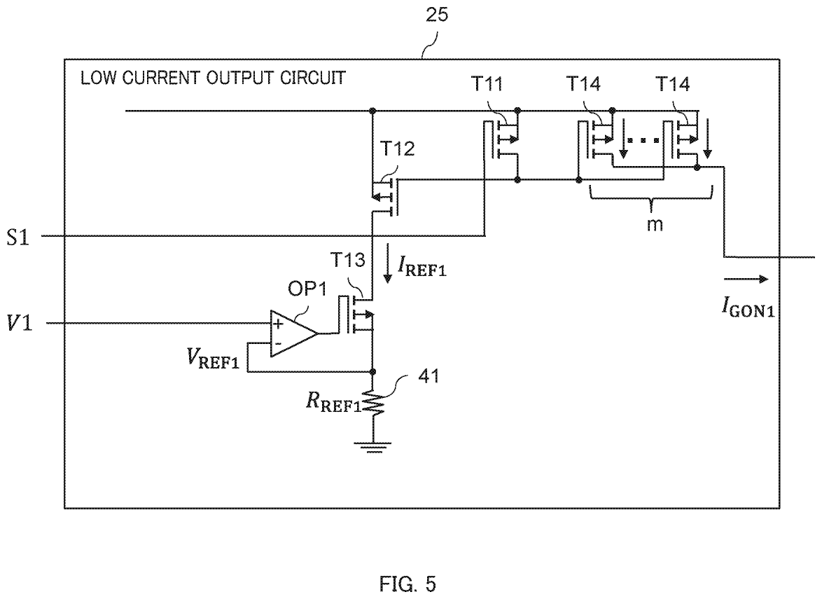

As illustrated in FIG. 4, the charging circuit 23 includes a low current output circuit 25, a timer circuit 26, and a high current output circuit 27. The charging circuit 23 will be explained with reference to FIGS. 5 to 9.

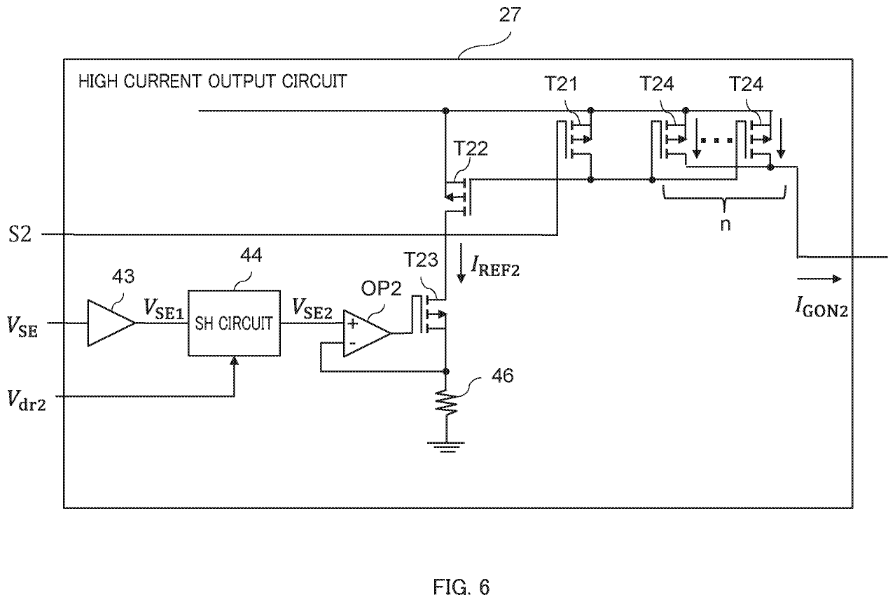

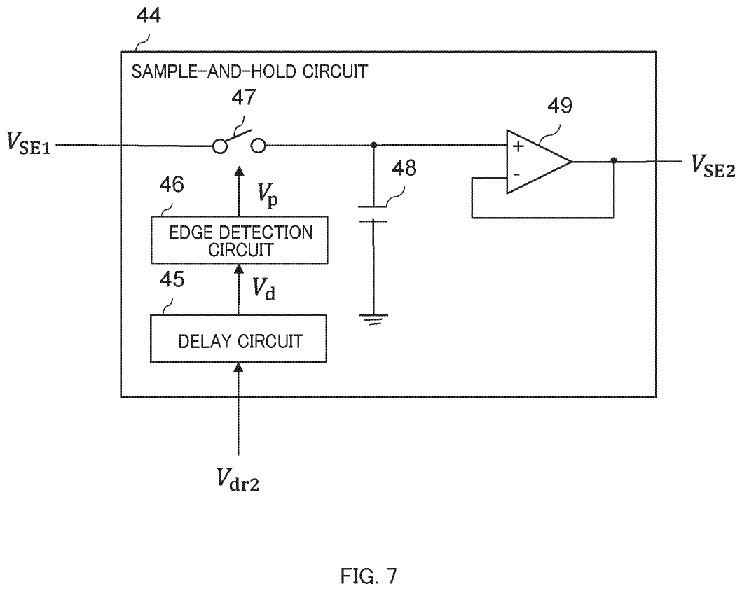

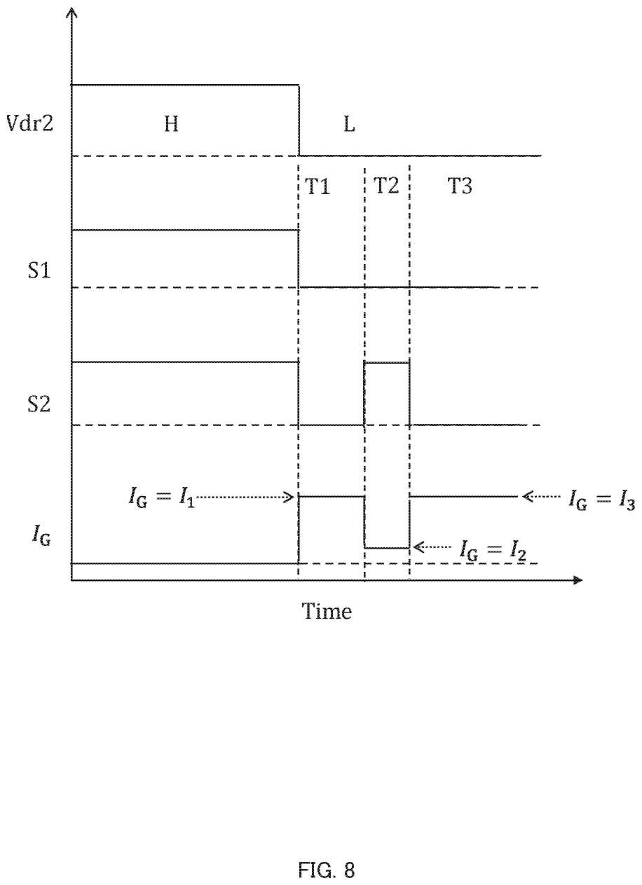

FIG. 5 is a diagram for explaining the low current output circuit 25. FIG. 6 is a diagram for explaining the high current output circuit 27. FIG. 7 is a diagram illustrating an example of a configuration of a sample-and-hold circuit 44. FIG. 8 is a diagram for explaining an operation of the charging circuit 23. In FIG. 8, the horizontal axis represents time. The vertical axis represents the drive signal Vdr2, the signal S1 and a signal S2 (details will be described later), and the gate current I_{G} of the IGBT 31.

The low current output circuit 25 is a circuit that outputs a current I_{GON1} smaller than a current I_{GON2} from the high current output circuit 27, which will be described later. The low current output circuit 25 receives the signal S1 and a predetermined voltage V, and outputs the current I_{GON1}.

As illustrated in FIG. 5, the low current output circuit 25 includes transistors T11 to T13, m transistors T14, and an operational amplifier OP1.

The transistor T11 is a switch to switch between setting the value of the current I_{GON1} to be outputted from the low current output circuit 25 to zero or setting the value to a predetermined value (described later), in response to the signal S1. The transistor T11 is a p-channel metal-oxide-semiconductor (MOS) transistor in an embodiment of the present disclosure. The transistor T11 is connected between a power supply and the gate electrode of the transistor T12 (described later).

The transistors T12 and T13, a resistor 41, and the operational amplifier OP1 are provided to generate a current I_{REF1}, which serves as the basis of the current I_{GON1}. The transistors T12 and T13 are p-channel MOS transistors in an embodiment t of the present disclosure.

The transistors T12 and T13 and the resistor 41 are connected in series in this order between the power supply and the ground. The resistance value of the resistor 41 is R_{REF1}, and a voltage V_{REF1} is generated across the resistor 41.

Here, the operational amplifier OP1 controls the transistor T13 such that the voltage at the source electrode of the transistor T13 matches a predetermined voltage V1.

The predetermined voltage V1 is applied to the non-inverting input terminal of the operational amplifier OP1. The inverting input terminal of the operational amplifier is connected between the transistor T13 and the resistor 41. The output terminal of the operational amplifier OP is connected to the gate electrode of the transistor T13.

Thus, when the signal S1 inputted to the transistor T11 is low, the value of the current I_{REF1} flowing through the transistor T12 results in V1/R_{REF1}. Meanwhile, when the signal S1 is high, the value of the current I_{REF1} flowing through the transistor T12 is zero.

The m transistors T14 are provided to cause the value of the current I_{GON1} to be m times the value of I_{REF1}. The m transistors T14 are p-channel MOS transistors in an embodiment of the present disclosure.

The m transistors T14 are connected in parallel to each other. Further, each of the drain electrodes of the m transistors T14 is connected to the power supply, and each of the gate electrodes thereof is connected to the gate electrode of the transistor T12.

Accordingly, when the signal S1 inputted to the transistor T11 is low, the transistor T12 is in a diode-connected state, and the transistor T12 and m transistors T14 constitute a current mirror circuit. Thus, the value of the current I_{GON1} that is to be outputted is equal to m×I_{REF1}.

Accordingly, when the signal S1 inputted to the transistor T11 is low, the value of the current I_{GON1} that is to be outputted is m×I_{REF1}. On the other hand, when the signal S1 is high, the value of the current I_{GON1} that is to be outputted is zero.

Note that the predetermined voltage V1 and the number m of the transistors T14 may be appropriately adjusted such that the value of the current I_{GON1} will be a desirable value.

The timer circuit 26 of FIG. 4 is a circuit that outputs, to the high current output circuit 27, the signal S2 defining time periods T1 to T3 in FIG. 8, in response to the drive signal Vdr2. The details of the time periods T1 to T3 will be described later.

Specifically, the timer circuit 26 outputs the low signal S2 for the time period T1 in response to the signal S1 going low. Upon completion of the time period T1, the timer circuit 26 outputs the high signal S2 for the time period T2. Upon completion of the time period T2, the timer circuit 26 outputs the low signal S2 for the time period T3.

The high current output circuit 27 is a circuit that outputs the current I_{GON2}. As will be described in detail later, the high current output circuit 27 outputs the current I_{GON2} having a current value of I₁, upon receiving the low signal S2 from the timer circuit 26 for the time period T1. The high current output circuit 27 outputs the current I_{GON2} having a current value of 12, upon receiving the high signal S2 from the timer circuit 26 for the time period T2. The high current output circuit 27 outputs the current I_{GON2} having a current value of I₃, upon receiving the low signal S2 from the timer circuit 26 for the time period T3.

As illustrated in FIG. 6, when the high current output circuit 27 is compared with the low current output circuit 25, the high current output circuit 27 differs therefrom particularly in including n number of transistors T24, an amplifier circuit 43, and a sample-and-hold circuit 44. In the following description, redundant explanations overlapping with the low-current output circuit 25 are omitted, a description will be given focusing on differences therefrom.

The amplifier circuit 43 is a circuit that amplifies, by a predetermined gain, a voltage corresponding to the current flowing after a sufficient time has elapsed since the beginning of the ON period of the IGBT 31. Note that the “current flowing after a sufficient time has elapsed since the beginning of the ON period of the IGBT 31” refers to, for example, a current that will be substantially constant after the IGBT 31 is turned on, and is also referred to as a “load current.” In an embodiment of the present disclosure, in response to a sufficient time having elapsed since the IGBT 31 is turned on, the current flowing through the IGBT 31 increases, then decreases, and becomes substantially constant (for example, a current of 600 A given by the solid line in FIG. 3A).

The amplifier circuit 43 receives the voltage V_{SE} applied to the resistor 13 (FIG. 4), and outputs an amplified voltage V_{SE1} to the sample-and-hold circuit 44.

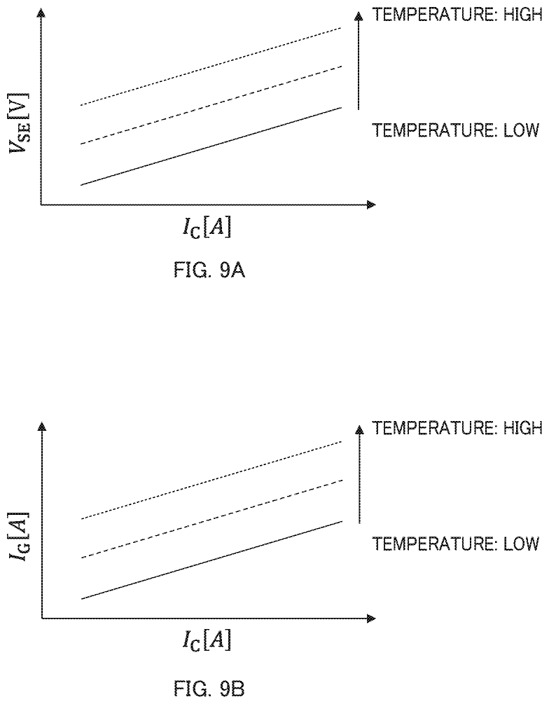

FIGS. 9A and 9B are diagrams describing the current I_{C} dependence and temperature dependence of the voltage V_{SE} (FIG. 4), and the current I_{C} dependence and temperature dependence of the current I_{G}. As described above, the voltage Vs is a voltage corresponding to the current I_{C} of the IGBT 31 generated across the resistor 13.

As illustrated in FIG. 9A, the voltage V_{SE} has a characteristic of increasing with a rise in temperature, since the resistor 13 has a positive temperature coefficient. The voltage V_{SE} has a characteristic of increasing with an increase in the current I_{C}. The amplifier circuit 43 can impart, to the current I_{G}, current I_{C} dependence and temperature dependence similar to those of the voltage V_{SE} by amplifying the voltage V_{SE} in accordance with the current I_{C} dependence and the temperature dependence of the voltage V_{SE}.

The sample-and-hold circuit 44 is a circuit that samples and holds the output of the amplifier circuit 43 based on a predetermined timing.

For example, the sample-and-hold circuit 44 samples the output of the amplifier circuit 43 at the timing at which the IGBT 31 switches from on to off, and holds it until the next time period during which the IGBT 31 is on.

The sample-and-hold circuit 44 is a circuit that samples and holds the voltage V_{SE1} in response to the drive signal Vdr2, and includes a delay circuit 45, an edge detection circuit 46, a switch 47, a capacitor 48, and a unity gain buffer 49 (FIG. 7).

The delay circuit 45 and the edge detection circuit 46 are circuits that generate a timing at which the voltage V_{SE1} is sampled. Specifically, the delay circuit 45 delays the drive signal Vdr2 by a “predetermined time period Tx”, and outputs a resultant signal as a signal Vd. Note that the “predetermined time period Tx” by which the delay circuit 45 delays the signal is, for example, a time period from when the drive signal Vdr2 goes low to turn off the IGBT 31 until when the IGBT 31 is actually turned off. As will be described in detail later, the sample-and-hold circuit 44 can obtain the maximum value of the load current I_{C}, by sampling the current of the IGBT 31 at such a timing.

The edge detection circuit 46 detects the falling edge of the signal Vd and outputs a pulse signal Vp to the switch 47.

The switch 47 is “ON” only during the time period during which the voltage V_{SE1} is applied to one end thereof and the pulse signal Vp is received. As a result, in response to the switch 47 being turned “on”, the voltage at the capacitor 48 results in the voltage V_{SE1}.

The unity gain buffer 49 is a buffer circuit that outputs the voltage at the capacitor 48 as a voltage V_{SE2}. Note that an adjustment circuit to adjust the gain and offset of the voltage V_{SE2} may be added (not illustrated).

The operation of the charging circuit 23 described above will be explained with reference to FIG. 8. The charging circuit 23 charges the capacitance of the gate electrode of the IGBT 31 with the gate current Is having a value of I₁ for the time period T1, in response to the drive signal Vdr2 reaching one logic level (the “low level” in an embodiment of the present disclosure, and the “one logic level” corresponds to a “first level”) (FIG. 8).

In this event, the signal S1 is low, and thus the value of the current I_{GON1} outputted by the low current output circuit 25 is m×I_{REF1}. Further, the signal S2 is low as well, and thus the value of the current I_{GON2} outputted by the high current output circuit 27 is n×I_{REF2}. Accordingly, the value I₁ of the gate current I_{G} during the time period T1 is m×I_{REF1}+n×I_{REF2}.

Note that according to an embodiment of the present disclosure, the gate current I_{G} is a current that increases with a rise in temperature. The gate current I_{G} is a current corresponding to the output of the amplifier circuit 43. The gate current I_{G} is a current corresponding to the voltage held by the sample-and-hold circuit 44.

After the time period T1, the charging circuit 23 charges the capacitance of the gate electrode of the IGBT 31 for the time period T2 with the gate current I_{G} with a value I₂ (FIG. 8).

In this event, the signal S1 is low, and thus the value of the current I_{GON} outputted by the low current output circuit 25 is m×I_{REF1}. Further, since the signal S2 is high, the value of the current I_{GON2} outputted by the high current output circuit 27 is zero. Accordingly, the value I₂ of the gate current I_{G} during the time period T2 is m×I_{REF1}. In other words, the value I₂ of the gate current I_{G} is smaller than I₁.

After the time period T2, the charging circuit 23 charges the capacitance of the gate electrode of the IGBT 31 with the gate current I_{G} with a value Is for the time period T3.

In this event, the signal S1 is low, and thus the value of the current I_{GON1} outputted by the low current output circuit 25 is m×I_{REF1}. Further, since the signal S2 is low as well, the value of the current I_{GON2} generated by the high current output circuit 27 is n×I_{REF2}. Accordingly, the value I₃ of the gate current I_{G} during the time period T3 is m×I_{REF1}+n×I_{REF2}, which is equal to I₁ during the time period T1.

Further, the values I₁ and Is of the gate current I_{G} increase with an increase in the current flowing after a sufficient time has elapsed since the beginning of the ON period of the IGBT 31, and they are greater than I₂. In an embodiment of the present disclosure, I₂ is set to about a value at which the charging of the capacitance of the gate electrode of the IGBT 31 is substantially stopped during the time period T2.

Note that the gate electrode corresponds to a “control electrode”. The gate current Is having a current value of I₁ corresponds to a “first current”. The gate current Is having a current value of I₂ corresponds to a “second current”. The gate current I_{G} having a current value of Is corresponds to a “third current”.

The time period T1 corresponds to a “first time period”. The time period T2 corresponds to a “second time period”. The time period T3 corresponds to a “third time period”. Note that in an embodiment of the present disclosure, each of the time periods T1 and T3 is set to be longer than the time period T2.

The off circuit 24 of FIG. 4 turns off the IGBT 31 in response to the drive signal Vdr2 reaching the other logic level (the “high level” in an embodiment of the present disclosure, and “the other logic level” corresponds to a “second level”).

The off circuit 24 includes a switch 28. In response to the drive signal Vdr2 going high, the switch 28 is electrically connected, so that the capacitance of the gate electrode of the IGBT 31 is discharged, thereby turning off the IGBT 31.

### <<Switching of IGBT 31 by LVIC 22>>

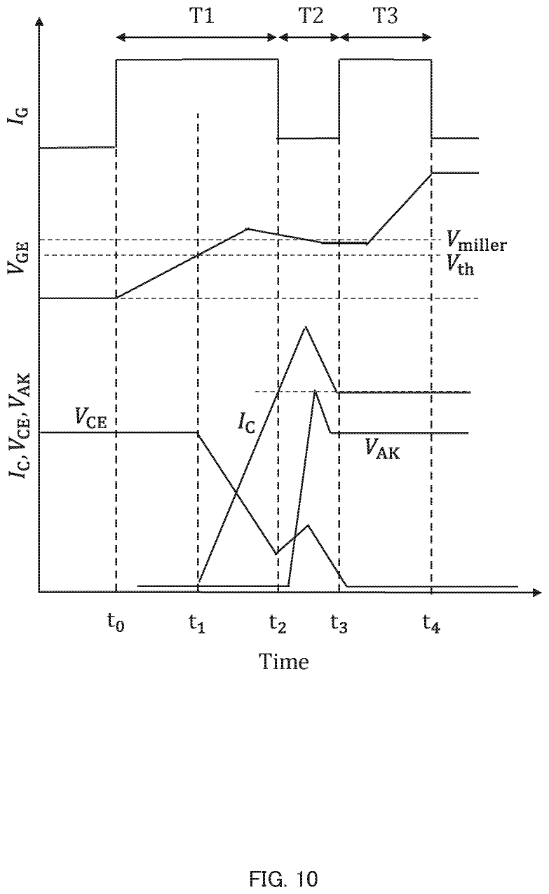

The switching of the IGBT 31 performed by the LVIC 22 will be described in detail. FIGS. 10 to 14 are diagrams explaining the switching of the IGBT 31 performed by the LVIC 22 according to an embodiment of the present disclosure.

The horizontal axis of FIG. 10 represents time. The vertical axis thereof represents the gate current I_{G} of the IGBT 31, the gate-emitter voltage V_{GE} of the IGBT 31, the voltage VAK across the FWD 32, the collector-emitter voltage V_{CE} of the IGBT 31, and the collector current I_{C} flowing through the IGBT 31.

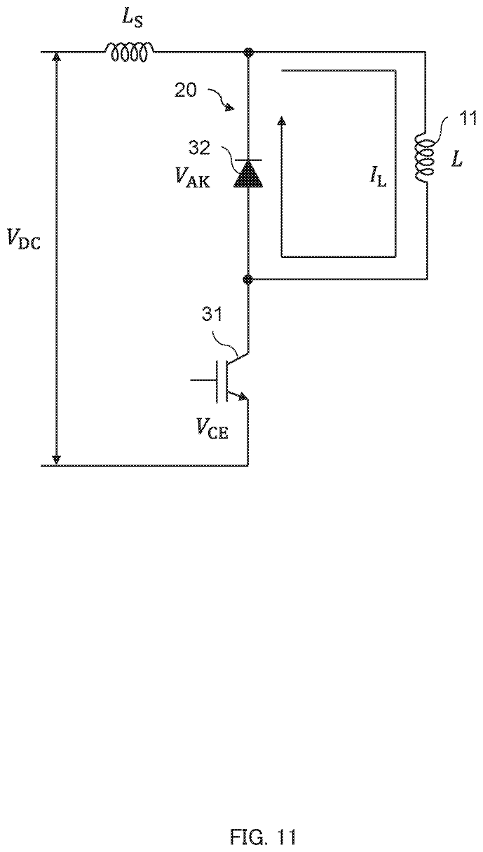

FIGS. 11 to 14 illustrate an equivalent circuit of the half-bridge circuit 20 during the time period during which the drive signal Vdr2 is low. In other words, the IGBT 30 of the upper arm is omitted because it is off. Further, the FWD 33 of the lower arm is omitted because the IGBT 31 is on and a current does not flow in a reverse-biased state.

Further, the inductance of wiring is illustrated as L_{S}. Further, a direct current voltage V_{DC} applied to the half-bridge circuit 20 is illustrated.

FIG. 11 is a diagram explaining the state during a time period from time t₀ to time t₁ in FIG. 10 (the first half of the time period T1 in FIG. 8). The time t0 is the time at which the time period T1 starts and the charging of the capacitance of the gate electrode of the IGBT 31 is started. The time t₁ is the time at which the charging of the capacitance of the gate electrode of the IGBT 31 progresses and the gate-emitter voltage V_{GE} of the IGBT 31 reaches the threshold voltage Vₜₕ of the IGBT 31.

During this time period, a forward current IL flows through the FWD 32. Further, the IGBT 31 is off, and thus the current I_{C} flowing through the IGBT 31 is substantially zero.

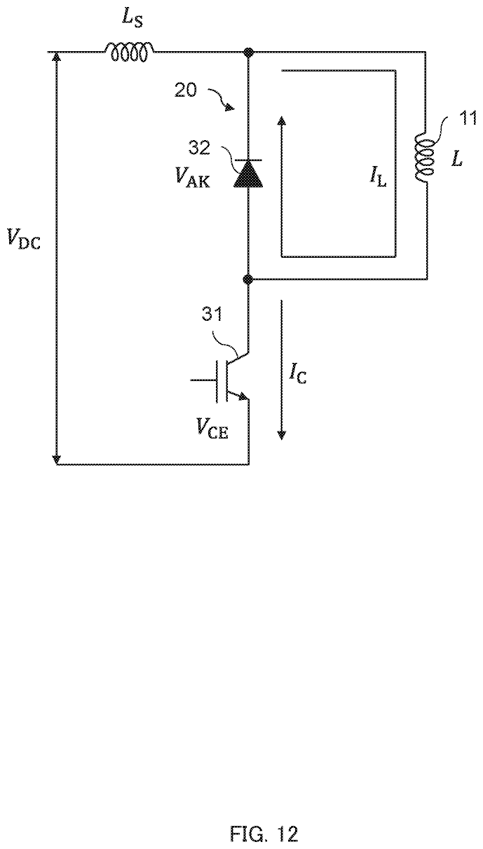

FIG. 12 is a diagram explaining the state during the time period from time t₁ to time t2 in FIG. 10 (the latter half of the time period T1 in FIG. 8). The time t2 is the time at which the time period T1 ends. As will be described in detail later, the end of the time period T1 (here, at time t2) is set to the time at which the current I_{C} reaches the current flowing through the inductor 11.

From time t₁, the charging of the capacitance of the gate electrode of the IGBT 31 further progresses, and the gate-emitter voltage V_{GE} of the IGBT 31 exceeds the threshold voltage Vₜₕ. During this time period as well, the forward current IL flows through the FWD 32.

Further, the current I_{C} flowing through the IGBT 31 increases, while the voltage V_{CE} decreases. Here, the larger the current I₁ for charging the capacitance of the gate electrode of the IGBT 31, the more rapidly the current I_{C} increases, and the more rapidly the voltage V_{CE} decreases. This reduces the switching loss of the IGBT 31.

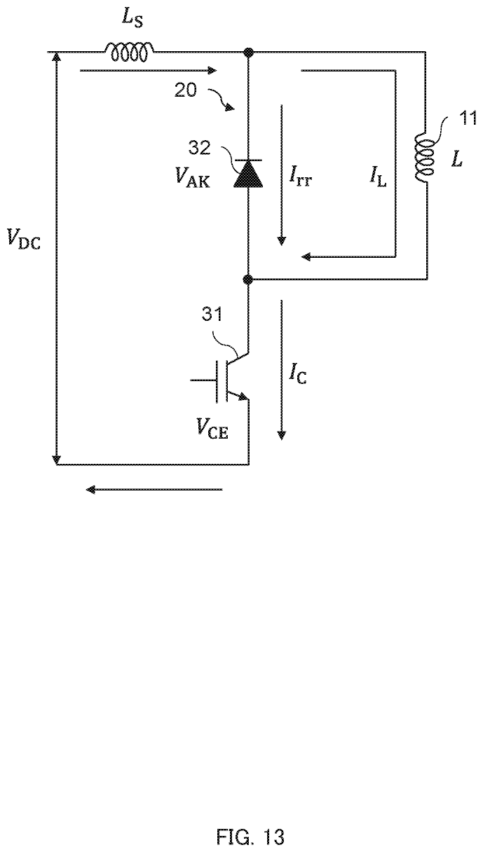

FIG. 13 is a diagram explaining the state during the time period from time t0 to time t3 (the time period T2 in FIG. 8). This time period corresponds to the time period T2. The time period T2 is set to be shorter than the time period T1.

During this time period, the voltage applied to the FWD 32 switches to the reverse direction, and a reverse recovery current Iᵣᵣ flows through the FWD 32. Due to the addition of this reverse recovery current Iᵣᵣ to the current I_{C}, it exceeds the current I_{C} after a sufficient time has elapsed since time to in the time period during which the IGBT 31 is on, and a peak value appears during the time period T2.

Further, as the time period T2 starts, the voltage V_{CE} rises. This is caused by a drop in the voltage across the inductance L_{S} of the wiring, as will be described below.

First, during the time period T1, the current I_{C} increases in order to charge the capacitance of the gate electrode of the IGBT 31, thereby causing a voltage drop across the inductance L_{S} of the wiring during the time period T1.

On the other hand, during the time period T2, the charging of the capacitance of the gate electrode of the IGBT 31 is stopped, and thus [symbol] an increase in the current I_{C} becomes more gradual than that during the time period T1. Accordingly, the voltage drop across the inductance L_{S} of the wiring is smaller than that during the time period T1. In association therewith, the voltage V_{CE} having dropped rises. Accordingly, as the time period T2 starts, the voltage V_{CE} rises.

Further, due to the reverse recovery current Iᵣᵣ flowing through the FWD 32, the voltage VAK across the FWD 32 rises. Here, the surge voltage V_{AKpeak}, which is the peak value of the voltage VAK, can be given by the following expression.

$${V}_{AK peak} = {V}_{DC} - {V}_{CE} ( t ) + {L}_{s} \frac{{dI}_{rr}}{dt} \qquad [ Math . 1 ]$$

In this expression, the voltage V_{CE} in the second term on the right side rises during the time period T2, as described above. The increase in the voltage V_{CE} in this event acts to reduce the surge voltage V_{AKpeak} according to the above expression.

In other words, with the provision of the time period T2 to reduce the speed of the charging of the gate capacitance of the IGBT 31, it is possible to reduce the surge voltage V_{AKpeak}.

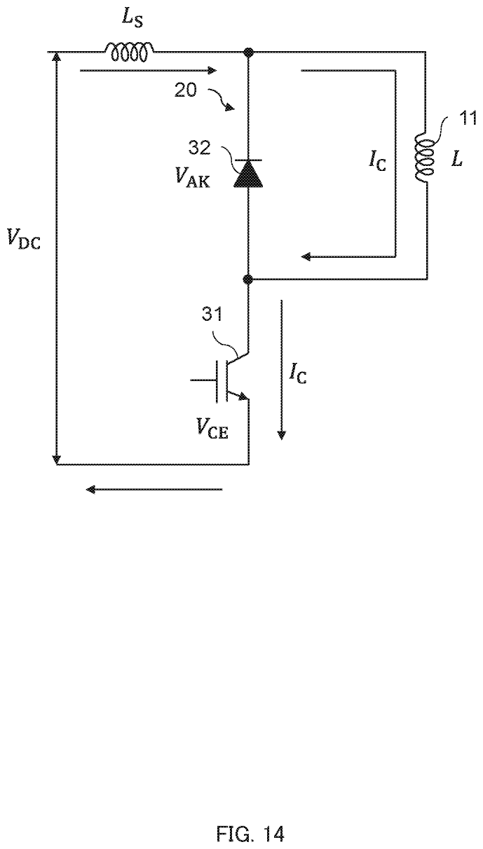

FIG. 14 is a diagram explaining the state during the time period from time t3 to time t4 in FIG. 10 (the time period T3 in FIG. 8). The time t3 is the time at which the time period T3 starts, and the time t4 is the time at which the time period T3 ends. During this time period, the current I_{C} and the voltage VAK transition at steady-state values.

### <<Current I₁ for Charging>>

In the switching control circuit according to an embodiment of the present disclosure, as described above, the larger the current I_{G} (having a current value of I₁) for charging the capacitance of the gate electrode of the IGBT 31 during the time period T1, the larger the current flowing after a sufficient time has elapsed since the beginning of the ON period of the IGBT 31 (also referred to as “steady-state value of the current I_{C} (or a constant value at which the current becomes substantially constant)”).

Here, unlike an embodiment of the present disclosure, a description will be given of a case in which the current I_{G} is constant regardless of the steady-state value of the current I_{C}. Then, an effect of adopting an embodiment of the present disclosure will be explained.

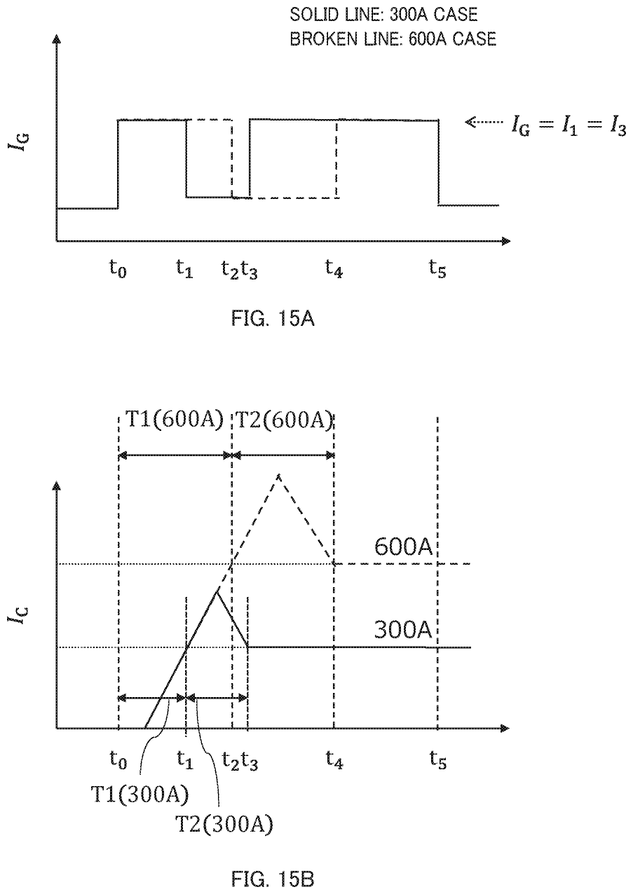

FIGS. 15A and 15B is a diagram explaining the time periods T1 and T2 when the current I_{G} for charging the capacitance of the gate electrode of the IGBT 31 is kept constant regardless of the steady-state value of the current IC. In these figures, the steady-state value of the current I_{C} is given in the case of 300 A (solid line) and in the case of 600 A (broken line).

In this example, in both cases, the time period T1 starts at time to. During the time period T1, in both cases, the current I_{C} begins to flow at substantially the same time and rises at substantially the same rate.

When the steady-state value of the current I_{C} is 300 A, the time at which the current I_{C} reaches the steady-state value is time t1, and the time period from time t₀ to time t₁ is set as the time period T1 (given as “T1 (300 A)” in FIG. 15B). On the other hand, when the steady-state value of the current I_{C} is 600 A, the time at which the current I_{C} reaches the steady-state value is time t2, and the time period from time t0 to time t2 is set as the time period T1 (given as “T1 (600 A)” in FIG. 15B).

Further, in this example, when the steady-state value of the current I_{C} is 300 A, the time period during which the reverse recovery current flows is from time t₁ to time t3, and this time period is set as the time period T2 (given as “T2 (300 A)” in FIG. 15B). On the other hand, when the steady-state value of the current I_{C} is 600 A, the time period during which the reverse recovery current flows is from time t2 to time t4, and this time period is set as the time period T2 (given as “T2 (600 A)” in FIG. 15B).

In other words, when the value I₁ of the current I_{G} for charging the capacitance of the gate electrode of the IGBT 31 is kept constant regardless of the steady-state value of the current I_{C}, it is needed to set the time periods T1 and T2 according to the steady-state value of the current I_{C}.

In an embodiment of the present disclosure, the time period T2 is set so as to include the time period during which the reverse recovery current flows through the FWD 32 when the load current flowing through the inductor 11 is at its maximum.

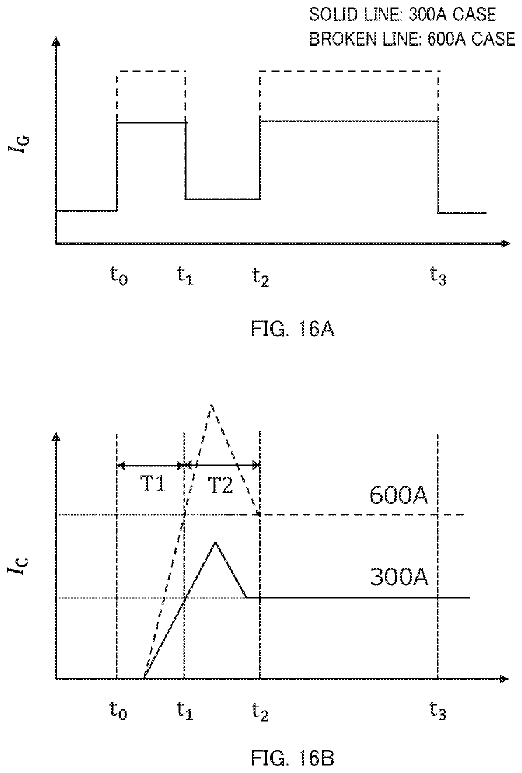

FIGS. 16A and 16B are diagrams explaining the time periods T1 and T2 in an embodiment of the present disclosure. In these figures as well, the steady-state value of the current I_{C} is given in the cases of 300 A and 600 A. In this example, the maximum value of the load current flowing through the inductor 11 is 600 A.

As described above, in an embodiment of the present disclosure, the value I₁ of the current I_{G} for charging the capacitance of the gate electrode of the IGBT 31 increases with an increase in the current flowing therethrough.

In the example of FIGS. 16A and 16B, the value I₁ of the current I_{G} when the steady-state value of the current I_{C} is 600 A is greater than the value I₁ when the steady-state value of the current I_{C} is 300 A (FIG. 16A). When the steady-state value of the current IC is 600 A, the time period during which the reverse recovery current flows through the FWD 32 is from time t₁ to time t2, and in an embodiment of the present disclosure, this time period is set to the time period T2 (FIG. 16B).

As can be seen from FIGS. 16A and 16B, when the steady-state value of the current I_{C} is 300 A, the time period during which the reverse recovery current flows through the FWD 32 is included in the time period T2 that has been set as described above.

In other words, in an embodiment of the present disclosure, common time periods T1 to T3 are set regardless of the steady-state value of the current I_{C}.

### <Numerical Simulation Results>

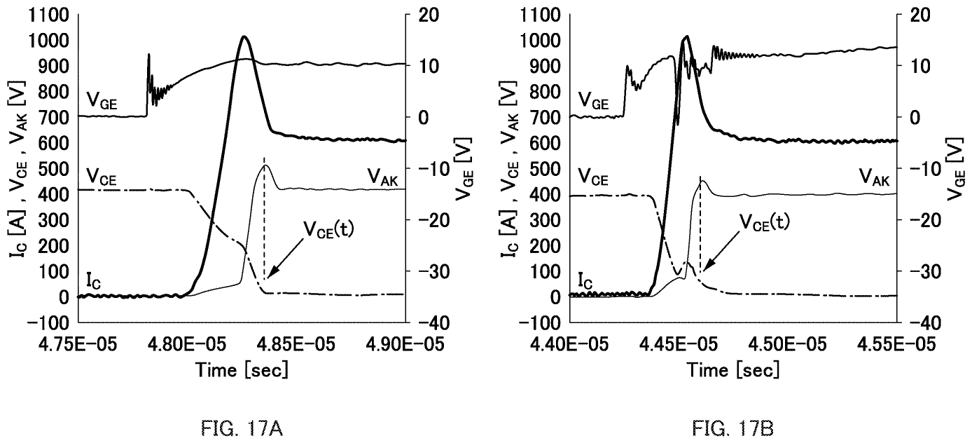

FIGS. 17 to 20 are numerical simulation results of the LVIC 22 according to an embodiment of the present disclosure and the typical voltage-driven LVIC 60, which is a comparative example.

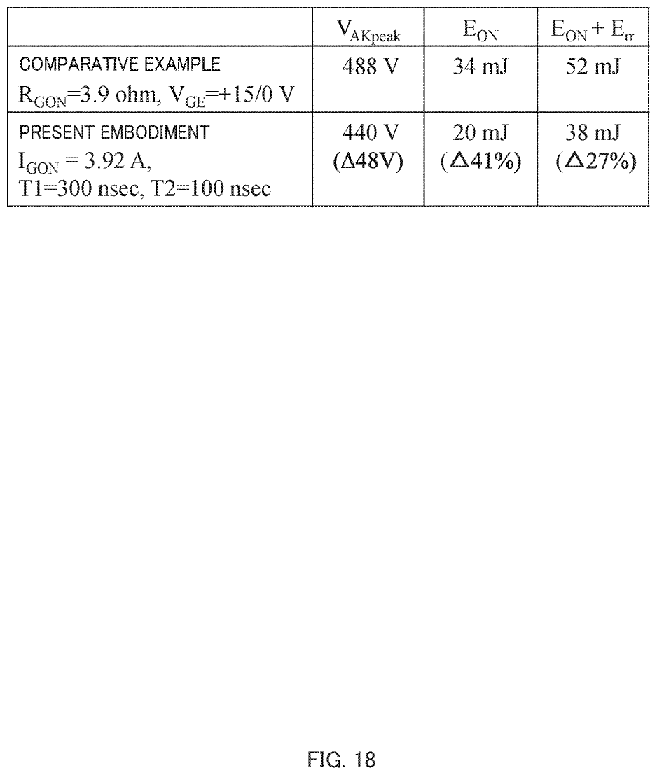

FIG. 17A illustrates the simulation results of the comparative example, while FIG. 17B illustrates the simulation results of an embodiment of the present disclosure. In these figures, the horizontal axis represents time. The vertical axis represents the current I_{C}, the voltage V_{CE}, the voltage VAK, and the voltage V_{GE}. FIG. 18 summarizes the results of FIGS. 17A and 17B.

The comparative example assumes a switching control circuit using the voltage-driven LVIC 60 illustrated in FIG. 2. Here, as illustrated in FIG. 18, the resistance R_{GON} is set to 3.9 [ohm].

Further, it is assumed in the comparative example that the gate-emitter voltage V_{GE} when turning on the IGBT 31 is +15 V, and the voltage V_{GE} when turning off the IGBT 31 is 0 V.

It is assumed in an embodiment of the present disclosure that the value I₁ of the current I_{G} to charge the capacitance of the gate electrode of the IGBT 31 is 3.92 [A], the time period T1 is 300 [nsec], and the time period T2 is 100 [nsec].

FIG. 18 illustrates the results of the surge voltage V_{AKpeak}, a switching loss E_{ON} by the IGBT 31, a switching loss E_{ON}+Eᵣᵣ obtained by combining the switching loss E_{ON} by the IGBT 31 and the switching loss Eᵣᵣ by the FWD.

According to an embodiment of the present disclosure, the surge voltage V_{AKpeak} is reduced by 48 V as compared to the comparative example. Further, the switching loss E_{ON} is reduced by 41% as compared to the comparative example. Furthermore, the switching loss E_{ON}+Eᵣᵣ is reduced by 27% as compared to the comparative example.

In other words, according to an embodiment of the present disclosure, it is possible to improve all of the surge voltage V_{AKpeak}, the switching loss EN, and the switching loss E_{ON}+Eᵣᵣ as compared to the typical voltage-controlled LVIC 60.

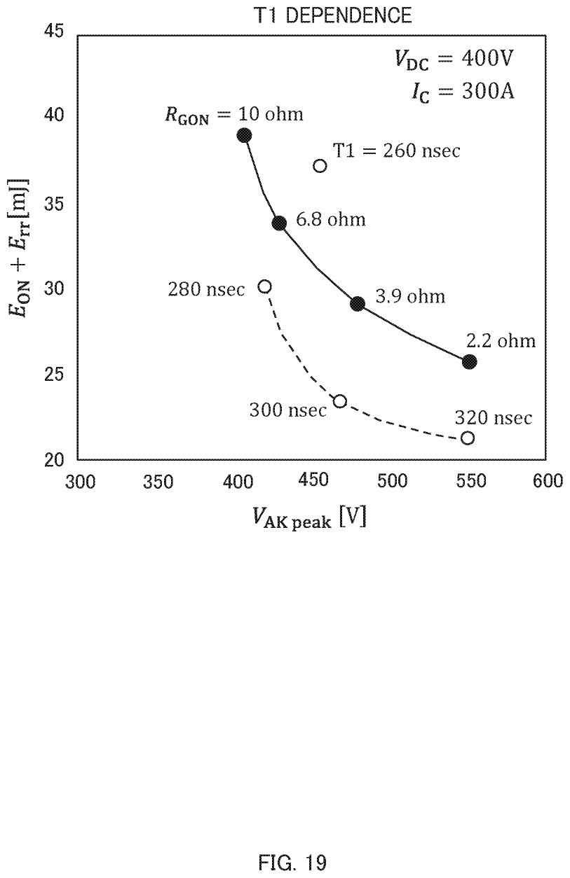

FIG. 19 illustrates the results of a numerical simulation investigating the dependence of the relationship between the surge voltage V_{AKpeak} and the switching loss E_{ON}+Eᵣᵣ on the time period T1. In this figure, the comparative example is given by black circles, while an embodiment of the present disclosure is given by white circles.

The comparative example (black circles) gives the results when the resistance R_{GON} was varied from 2.2 [ohm] to 10 [ohm]. An embodiment of the present disclosure (white circle) gives the results when the time period T1 was varied from 280 [nsec] to 320 [nsec].

From the results of the comparative example, it can be seen that there is a trade-off relationship between the surge voltage V_{AKpeak} and the switching loss E_{ON}+Eᵣᵣ.

From the results of an embodiment of the present disclosure, it can be seen that when the time period T1 falls within the range of from 280 [nsec] to 320 [nsec], the trade-off relationship has been improved relative to that in the comparative example.

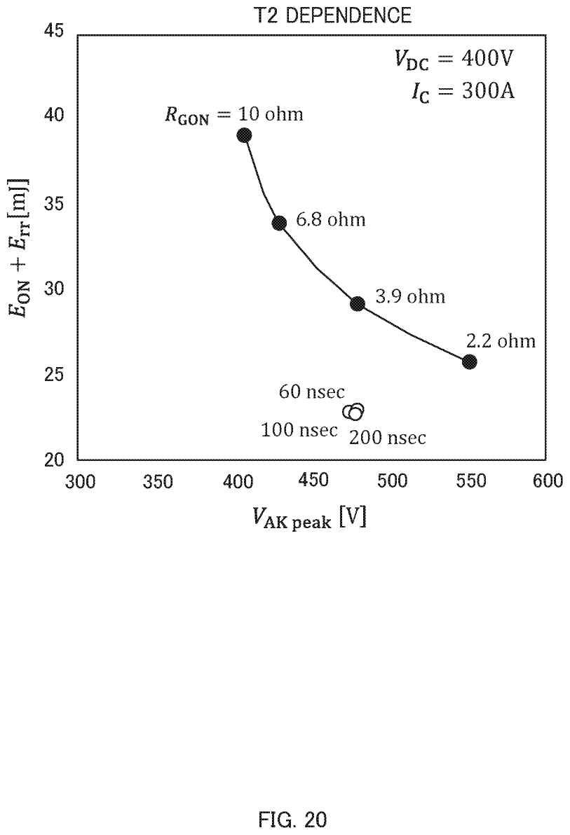

FIG. 20 illustrates the results of the numerical simulation investigating the dependence of the relationship between the surge voltage V_{AKpeak} and the switching loss E_{ON}+Eᵣᵣ on the time period T2. In this figure as well, the comparative examples are given by black circles, while an embodiment of the present disclosure is given by white circles.

The comparative example (black circles) is the same as in FIG. 19, while an embodiment of the present disclosure (white circles) give the results when the time period T2 is varied from 60 [nsec] to 200 [nsec].

From the results of an embodiment of the present disclosure, it can be seen that when the time period T2 falls within the range of from 60 [nsec] to 200 [nsec], the results are substantially unaffected. In other words, it can be seen that a strict setting of the time period T2 is not necessary.

As explained hereinabove, according to the power module 10 of an embodiment of the present disclosure, the trade-off relationship between the surge voltage and the switching loss of the half-bridge circuit 20 is improved.

### SUMMARY

The LVIC 22 of an embodiment described above is a switching control circuit for the load drive circuit that includes the IGBT 30 on the power supply side, the IGBT 31 on the ground side, and the FWD 32, the IGBT 30 and the IGBT 31 being connected in series, the FWD 32 being connected in parallel to IGBT 30, the load drive circuit being configured to drive the load, the switching control circuit being configured to switch the IGBT 31, the switching control circuit including: the charging circuit 23 configured to, in response to the drive signal reaching one logic level, charge the capacitance of the gate electrode of the IGBT 31, for the time period T1, with the current I₁ that increases with an increase in the current flowing after a sufficient time has elapsed since the beginning of the ON period of the IGBT 31, and then charge the capacitance, for the time period T2, with the current I₂ that is smaller than the current I₁; and an off circuit 24 configured to, in response to the drive signal reaching the other logic level, turn off the IGBT 31, the time period T2 including the time period during which the reverse recovery current flows through the FWD 32 when the load current flowing through the load reaches its maximum.

According to such a configuration, the capacitance of the gate electrode of the IGBT 31 is charged with a large current during the time period T1, and thus the current I_{C} rapidly increases until it reaches the load current. In association therewith, the voltage V_{CE} is rapidly reduced. Accordingly, the switching loss is reduced.

Furthermore, during the time period T2, which starts immediately before the reverse recovery current flows through the FWD 32, the charging of the capacitance of the gate electrode of the IGBT 31 with the large current is stopped, and in association therewith, the voltage V_{CE} rises. Accordingly, the surge voltage is reduced. From the above, the relationship between the switching loss and the surge voltage is improved with a simple configuration.

In the LVIC 22, the charging circuit 23 charges the capacitance of the gate electrode of the IGBT 31 for the time period T1 with the current I₁ that increases with a rise in temperature. According to such a configuration, the current I_{C} can be given a temperature dependence similar to the temperature dependence of the voltage V_{SE}. This makes it possible to optimize the switching loss and the surge voltage.

Further, in the LVIC 22, the time period T2 is shorter than the time period 1. According to such a configuration, when the IGBT 31 is to be turned on, it is possible to sufficiently charge the capacitance of the gate electrode of the IGBT 31.

Further, the LVIC 22 includes the amplifier circuit 43 configured to amplify, by the predetermined gain, the voltage corresponding to the current flowing after the sufficient time has elapsed since the beginning of the ON period of the IGBT 31, and the charging circuit 23 charges the capacitance of the gate electrode of the IGBT 31, for the time period T1, with the current I₁ corresponding to the output of the amplifier circuit 43. Accordingly, the LVIC 22 becomes more likely to operate under an optimal condition of the switching loss and the surge voltage.

Further, the LVIC 22 includes the sample-and-hold circuit 44 configured to sample and hold the output of the amplifier circuit 43, based on the predetermined timing, and the charging circuit 23 charges the capacitance of the gate electrode of the IGBT 31, for the time period T1, with the current I₁ corresponding to the voltage held by the sample-and-hold circuit 44. According to such a configuration, the load current is more likely to be reflected in the current I₁, and the LVIC 22 is more likely to operate under the optimal conditions for the switching loss and the surge voltage.

Further, in the LVIC 22, the charging circuit 23 charges the capacitance for the time period T3 with the current I₃, after the time period T1, the current Is being greater than the current I₂. According to such a configuration, when the IGBT 31 is to be turned on, it is possible to sufficiently charge the capacitance of the gate electrode of the IGBT 31.

The charging circuit 23 charges the capacitance, for the time period T3, with the current I₃ that increases with an increase in the current flowing after a sufficient time has elapsed since the beginning of the ON period of the IGBT 31. According to such a configuration, when the IGBT 31 is to be turned on, it is possible to sufficiently charge the capacitance of the gate electrode of the IGBT 31.

The power module 10 of an embodiment includes: the load drive circuit including the IGBT 30 on the power supply side, the IGBT 31 on the ground side, and the FWD 32 that is connected in parallel to the IGBT 30, the load drive circuit being configured to drive the load; the resistor 13 configured to generate the voltage corresponding to the current of the IGBT 31; and the LVIC 22 configured to switch the IGBT 31, the LVIC 22 including the charging circuit 23 configured to, in response to the drive signal reaching one logic level, charge the capacitance of the gate electrode of the IGBT 31, for the time period T1, with the current I₁ that increases with a rise in the voltage across the resistor 13, and then charge the capacitance, for the time period T2, with the current I₂ that is smaller than the current I₁, and an off circuit 24 configured to, in response to the drive signal reaching the other logic level, turn off the IGBT 31, the time period T2 including the time period during which the reverse recovery current flows through the FWD 32 when the load current flowing through the load reaches its maximum.

According to such a configuration, the capacitance of the gate electrode of the IGBT 31 is charged with a large current for the time period T1, and thus the current I_{C} rapidly increases until it reaches the load current. This rapidly reduces the voltage V_{CE}. Accordingly, the switching loss is reduced.

Furthermore, during the time period T2 that starts immediately before the reverse recovery current flows through the FWD 32, the charging of the capacitance of the gate electrode of the IGBT 31 with the large current is stopped, and the voltage V_{CE} rises. Accordingly, the surge voltage is reduced. From the above, the relationship between the switching loss and the surge voltage is improved with a simple configuration.

The present disclosure is directed to provision of a switching control circuit capable of improving the relationship between power loss and surge voltage with a simple configuration.

According to the present disclosure, it is possible to provide a switching control circuit capable of improving the relationship between power loss and surge voltage with a simple configuration.

What is claimed is:

1. A switching control circuit for a load drive circuit that includes
a first switching device on a power supply side of the switching control circuit,
a second switching device on a ground side of the switching control circuit, and connected to the first switching device in series, the second switching device having a control electrode that has a capacitance, and
a free-wheeling diode connected in parallel to the first switching device,
the load drive circuit being configured to drive a load to have a load current flow therethrough, the switching control circuit being configured to switch the second switching device, the switching control circuit comprising:
a charging circuit configured to, in response to a drive signal reaching a first level,
charge the capacitance of the control electrode of the second switching device, for a first time period with a first current, the first current increasing with an increase in the load current, and
subsequently charge the capacitance, for a second time period, with a second current that is smaller than the first current; and
an off circuit configured to, in response to the drive signal reaching a second level, turn off the second switching device,
the second time period including a time period during which a reverse recovery current flows through the free-wheeling diode when the load current reaches a maximum thereof.

2. The switching control circuit according to claim 1, wherein the first current further increases with a rise in a temperature.

3. The switching control circuit according to claim 1, wherein the second time period is shorter than the first time period.

4. The switching control circuit according to claim 1, further comprising:
an amplifier circuit configured to amplify, by a predetermined gain, a voltage corresponding to a current flowing through the second switching device, wherein
the first current further corresponds to an output of the amplifier circuit.

5. The switching control circuit according to claim 4, further comprising:
a sample-and-hold circuit configured to sample and hold the output of the amplifier circuit, based on a predetermined timing, wherein
the first current further corresponds to a voltage held by the sample-and-hold circuit.

6. The switching control circuit according to claim 1, wherein the charging circuit charges the capacitance for a third time period with a third current, after the second time period, the third current being greater than the second current.

7. The switching control circuit according to claim 6, wherein the charging circuit charges the capacitance, for the third time period, with the third current that increases with the load current.

8. A semiconductor device, comprising:
a load drive circuit, including:
a first switching device on a power supply side of the semiconductor device,
a second switching device on a ground side of the semiconductor device, the second switching device having a control electrode that has a capacitance, and
a free-wheeling diode that is connected in parallel to the first switching device,
the load drive circuit being configured to drive a load to have a load current flow therethrough;
a resistor configured to generate a voltage corresponding to a current of the second switching device; and
a switching control circuit configured to switch the second switching device, the switching control circuit including
a charging circuit configured to, in response to a drive signal reaching a first level,
charge the capacitance of the control electrode of the second switching device, for a first time period, with a first current that increases with a rise in a voltage across the resistor, and
subsequently charge the capacitance, for a second time period, with a second current that is smaller than the first current, and
an off circuit configured to, in response to the drive signal reaching a second level, turn off the second switching device,
the second time period including a time period during which a reverse recovery current flows through the free-wheeling diode when the load current reaches a maximum thereof.
